(19) United States
(12) Patent Application Publication
(10) Pub. No.: US 2018/0351552 A1
(43) Pub. Date: Dec. 6, 2018

(54) TRIGGER CIRCUIT

(71) Applicant: PIXART IMAGING INC., Hsin-CHU (TW)

(72) Inventors: PENG-SHENG CHEN, HSIN-CHU (TW); JUI-TE CHIU, HSIN-CHU (TW); HAN-CHI LIU, HSIN-CHU (TW)

(21) Appl. No.: 15/612,729

(22) Filed: Jun. 2, 2017

(51) Int. Cl. H03K 17/967; H01H 13/70; H03K 17/96; G06F 3/033

(52) U.S. Cl. CPC H03K 17/967; G06F 3/033; H03K 17/96; H01H 13/70

(57) ABSTRACT

The present disclosure illustrates a trigger circuit applied to an electronic apparatus having a plurality of triggers, which includes a trigger switch and a trigger network. The trigger switch, corresponding to one of the plurality of triggers, has a first end and a second end, in which the first end of the trigger switch is connected with a pad, and the second end of the trigger switch is connected with a voltage source having a first voltage value. Further, the trigger network, corresponding to a rest of the plurality of triggers, has at least one trigger sub-circuit electrically connected with the pad, in which the trigger network has an impedance value. When the trigger switch is triggered, due to an impedance value of the trigger network, the first voltage value will be detected at the pad.

### BACKGROUND

### 1. Technical Field

The present disclosure is related to a trigger circuit, and more particularly to a pin-shared trigger circuit.

### 2. Description of Related Art

In modern technology, electronic products are all formed with circuits. When a circuit state needs to be changed or a signal needs to be sent, a trigger is usually used. Conventional simple circuit designs are intuitive, with the number of triggers often corresponding to the number of functions provided.

However, in recent years, electronic products are made to be more tiny and delicate. In these electronic products with limited space, the complexity of the circuit design often increases with the number of functions thereof. Therefore, a pin-shared conception was developed to alleviate the foregoing issue. In brief, when a plurality of triggers sharing one pin are triggered in combination, a corresponding specific value will be detected via a detecting circuit at a pad at the position of the pin, and then determine if the specific value is located within a certain interval corresponding to a specific function. Each combination of the triggers can thereby be distinguished from each other by this feature.

Moreover, the button is one of the most widely used type of trigger in the art. FIG. 1A depicts a conventional pin-shared trigger circuit with two corresponding buttons A, B (not shown). FIG. 1A shows a trigger network 107 sharing one pin via a pad 105 and a circuit 103 that can detect a specific value (e.g., voltage value) at the pad so as to further detect the triggering situation in the trigger network 107.

In this case, R1 and R2 are names and resistance values of different resistors. Reference is next made to FIG. 1B and 1A, which depict a design of trigger threshold intervals illustrating the conventional pin-shared trigger circuit with two corresponding buttons. In practice, trigger thresholds can be designed as 0, which means that the total impedance is 0, V(R1) can represent that the total impedance is R1, V(R2) can represent that the total impedance is R2, and V(R1//R2) can represent that R1 and R2 are connected in a parallel manner and the total impedance is (R1//R2). In which, if a detected voltage value is located in an interval from 0˜V(R1//R2), it means that there is no key triggered; if the detected voltage value is located in an interval from V(R1)˜V(R2), it means that a trigger A′ is triggered; if the detected voltage value is located in an interval from more than V(R2), it means that a trigger B′ is triggered; and, if the detected voltage value is located in an interval from V(R1//R2)˜V(R1), it means that the trigger A′ and the trigger B′ are both triggered. Specifically, the way of distinguishment is to detect the voltage value at the pad and check which of the trigger threshold intervals the voltage value belongs to determine the corresponding trigger (or button etc.).

In particular, conventionally, if a user needs to add a new trigger (e.g., a trigger C′), the user might also need to add one more resistor R3 (R3 representing the name of the resistor and its resistance value). However, the circuit 103 must detect the voltage value which is made by a combination of different resistors such as R1, R2 and R3, and determine which of the trigger threshold intervals the voltage value belongs to. The times of determination needed are increased by powers of 2. That is, adding more triggers (i.e., more new resistors) will lead to a more complex computation to determine more trigger threshold intervals. Therefore, the trigger circuit will require a larger area and bring about a larger power consumption accordingly. This also makes the trigger threshold intervals become smaller, and makes judgment errors occur more frequently.

### SUMMARY

In view of the above, the present disclosure provides a pin-shared trigger circuit applied to an electronic apparatus. The trigger circuit includes a trigger switch and a trigger network. The trigger switch corresponds to one of the triggers of the electronic apparatus, and the trigger network corresponds to a rest of the triggers of the electronic apparatus.

An exemplary embodiment of the present disclosure provides a trigger circuit. The trigger circuit is coupled with a pad, and applied to a plurality of triggers of an electronic apparatus. The trigger circuit includes a trigger switch and a trigger network. The trigger switch corresponds to one of the triggers of the electronic apparatus, and has a first end and a second end. The first end of the trigger switch is connected electrically with the pad, and the second end of the trigger switch is connected electrically with a voltage source having a first voltage value. Further, the trigger network corresponds to a rest of the triggers of the electronic apparatus, and has at least one trigger sub-circuit connected electrically with the pad, and an impedance value. When the trigger switch is triggered, due to the impedance value of the trigger network, the first voltage value will be at the pad.

The present disclosure provides a way for achieving the pin-shared mechanism, namely, by way of using a power or a ground wire.

For example, a trigger that we use frequently (e.g., a left key, a right key or a central key of a computer mouse) can be made into a pin-shared trigger in the aforementioned manner. Therefore, three triggers can be used with only the complexity of two triggers.

To sum up, the present disclosure provides a design of the trigger switch in which a new impedance device (e.g., a resistor) need not be added when adding another trigger so as to achieve the purposes of saving hardware costs (due to there being no need to add an additional impedance device), reducing power consumption, and decreasing the occurrence of judgment errors (due to the trigger threshold intervals being too small), by only slightly increasing the complexity of the trigger circuit.

In order to further understand the techniques, means and effects of the present disclosure, the following detailed descriptions and appended drawings are hereby referred to, such that, and through which, the purposes, features and aspects of the present disclosure can be thoroughly and concretely appreciated; however, the appended drawings are only provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1A exemplarily depicts a conventional pin-shared trigger circuit with two corresponding buttons according to an embodiment of the present disclosure.

FIG. 1B exemplarily depicts trigger threshold intervals of the conventional pin-shared trigger circuit with two corresponding buttons according to an embodiment of the present disclosure.

FIG. 2A is an embodiment of a pin-shared trigger circuit of the present disclosure.

FIG. 2B illustrates a design of trigger threshold intervals of an embodiment of the pin-shared trigger circuit of the present disclosure.

FIG. 2C is a mapping table of a trigger threshold interval-trigger of the embodiment of the pin-shared trigger circuit according to the present disclosure.

FIG. 3A is another embodiment of a pin-shared trigger circuit of the present disclosure.

FIG. 3B illustrates trigger threshold intervals of another embodiment of the pin-shared trigger circuit of the present disclosure.

FIG. 3C is a mapping table of a trigger threshold interval-trigger of another embodiment of the pin-shared trigger circuit according to the present disclosure.

FIG. 4 is a schematic perspective view illustrating an embodiment of the pin-shared trigger circuit of the present disclosure in application.

FIG. 5 is a diagram of an embodiment of the pin-shared trigger circuit of the present disclosure in application.

### DESCRIPTION OF THE EXEMPLARY EMBODIMENTS

Reference will now be made in detail to the exemplary embodiment of the present disclosure, examples of which are illustrated in the accompanying drawings. Wherever possible, the same reference numbers are used in the drawings and the description to refer to the same or like parts.

[Trigger Switch Connected with a Constant Voltage Source]

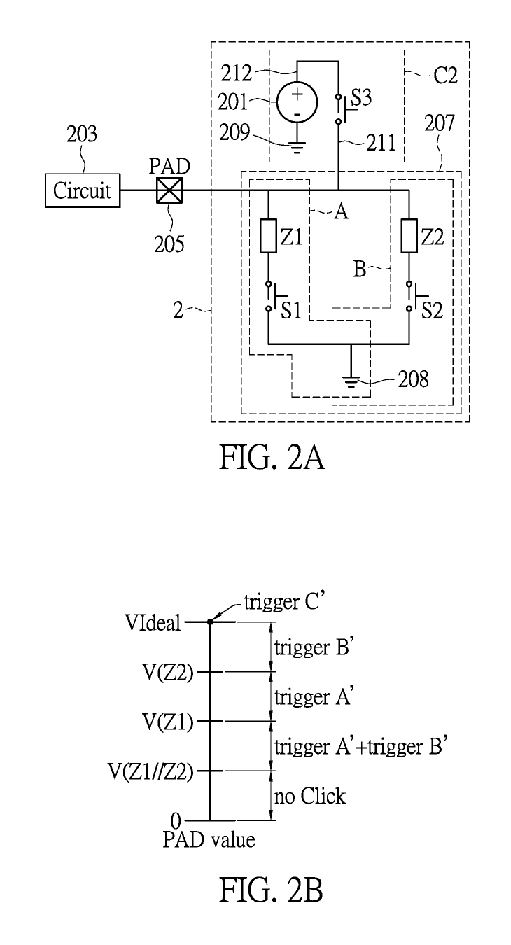

First of all, referring to FIG. 2A, FIG. 2A shows an embodiment of a pin-shared trigger circuit of the present disclosure. Via a trigger C′, an additional trigger can be disposed in the present disclosure without having to add a new impedance device Z3, thereby saving hardware costs while only slightly increasing the complexity of the circuits.

In practice, a pin-shared trigger circuit will have a plurality of triggers (e.g., buttons, virtual buttons or any type of switch) corresponding to an electronic apparatus (e.g., a mouse, a keyboard or a touch panel apparatus).

In FIG. 2A, a trigger circuit 2 of the exemplary embodiment of the present disclosure is coupled with a circuit 203 via a pad 205. The circuit 203 could be but not limited to a detecting circuit or other kinds of circuits.

Further, the trigger circuit 2 includes: a trigger switch C2 and a trigger network 207, in which the trigger switch C2 and the trigger network 207 are both electric circuits. The trigger switch C2 controls a corresponding one of a plurality of triggers of an electronic apparatus. The trigger network 207 controls a corresponding rest of the plurality of triggers of the electronic apparatus.

In FIG. 2A, a composition of the trigger switch C2 includes a switch S3, a voltage source 201 and a ground wire 209, in which the switch S3, the voltage source 201 and the ground wire 209 are coupled electrically. The trigger switch C2 has a first end 211 and a second end 212 separately connected with two ends of the switch S3, the first end 211 being electrically connected with the pad 205, and the second end 212 being electrically connected with the voltage source 201. The voltage source 201 provides a first voltage value. The trigger switch C2 is an electric loop of the trigger C′. That is, when the switch S3 is ‘on’, the trigger switch C2 is triggered (i.e., the trigger C′ is triggered).

Furthermore, it should be noted that the voltage source 201 connected with the second end 212 of the trigger switch C2 should be the voltage source 201 which can output a constant voltage. The voltage source 201 can be: an ideal voltage source, a power, a ground wire or a band-gap reference.

In an embodiment which the trigger switch C2 is connected with the ideal voltage source or the power, it can be detected that the first voltage value is more than zero at the pad 205 when the ideal voltage source or the power continually outputs. In addition, in an embodiment which the trigger switch C2 is directly connected with the ground wire (not having any other voltage source), it could be detected that the first voltage value which is equal to zero at the pad 205.

In FIG. 2A, the trigger network 207 has a trigger sub-circuit A and a trigger sub-circuit B, and is electrically connected with the pad 205. The trigger sub-circuit A is a circuit of the trigger A′, and the trigger sub-circuit B is a circuit of the trigger B′. That is to say, when a switch S1 or S2 are ‘on’, the trigger sub-circuit A or B are triggered (i.e., the trigger A′ and B′ are triggered).

The trigger sub-circuit A in FIG. 2A includes: an impedance device Z1, the switch S1 and a ground wire 208, in which the impedance device Z1, the switch S1 and the ground wire 208 are electrically connected to each other. The trigger B has a similar composition with that of the trigger sub-circuit A, and includes: an impedance device Z2, a switch S2 and a ground wire 208, in which the impedance device Z2, the switch S2 and the ground wire 208 are electrically connected to each other. The numbers of trigger sub-circuits, components, or manners of connections in the trigger network 207 are not limited by that disclosed in the present disclosure.

Furthermore, following the natural law, the trigger network 207 which is an electronic circuit naturally has an impedance value. When the trigger circuit C2 is triggered, due to the impedance of the trigger network 207, an electric current will not flow to the trigger network 207, but will flow through the voltage source 201 and the trigger switch C2 to the pad 205 which have less impedance (or zero impedance) than the trigger network 207. Therefore, when the one of the triggers corresponding to the trigger switch C2 and at least one of the rest of the triggers corresponding to the trigger network 207 are triggered at the same time, the circuit 203 can only detect the first voltage value at the pad 205. That is, since the trigger C′ and the other triggers A′ and B′ do not produce a collective effect, only a one-time determination need be conducted for the trigger threshold intervals.

Reference is next made to FIGS. 2A and 2B. FIG. 2B illustrates trigger threshold intervals of the embodiment of the pin-shared trigger circuit of the present disclosure.

A combination of the triggers corresponding to the trigger circuit 2 is such as “no triggers triggered”, “triggering trigger A′”, “triggering trigger B′”, “triggering trigger A′ and trigger B′”, or “triggering trigger C′”. The way of determining the triggered state of the triggers is by determining, via the circuit 203, which trigger threshold interval the voltage value at the pad 205 belongs to when a combination is triggered.

In the embodiment, when detecting that the voltage value at the pad 205 is between V(Z1) to V(Z2), trigger A′ will be determined as being triggered; when detecting that the voltage value at the pad 205 is between V(Z2) to V, trigger B′ will be determined as being triggered; when detecting that the voltage value at the pad 205 is between V(Z1//Z2) to V(Z1), trigger A′ and trigger B′ will be determined as being triggered at the same time; when detecting the voltage value at the pad 205 between zero to V(Z1//Z2), it will be determined that no trigger is triggered (i.e., no Click). In addition, when detecting that the voltage value at the pad 305 is equal to ‘V’ (as will be described later), “trigger C′” may be determined as being triggered.

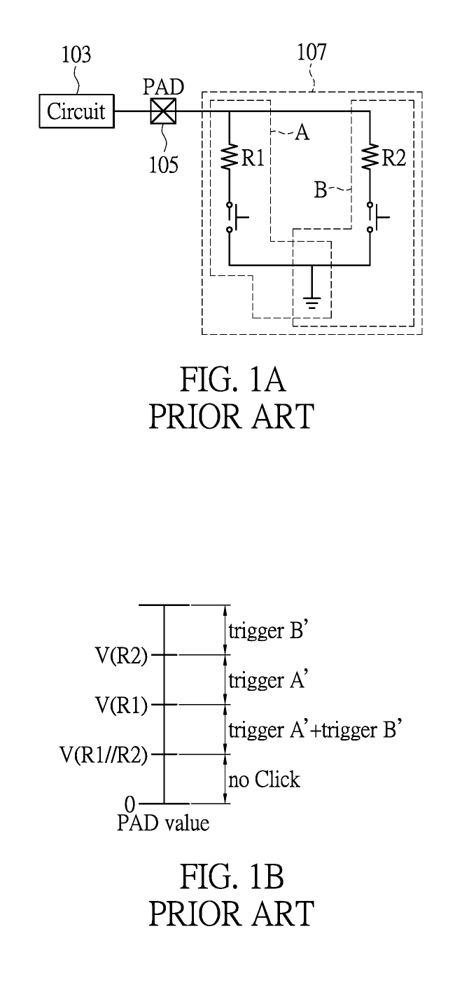

More specifically, comparing FIG. 2B with FIG. 1B, in the upper section of FIG. 2B, there is an additional threshold (corresponding to an addition voltage value such as a constant voltage value, ‘V’) for the trigger C′ in FIG. 2B. In the trigger circuit 2 in the embodiment, a principle illustrated in FIG. 2A is used. In addition to relying on the voltage values generated by different combinations of the impedance devices Z1, Z2, another way of determining the triggered trigger is by cooperatively applying the trigger switch C2 of a constant voltage source 201, thereby serving to increase the number of the triggers.

Therefore, via the foregoing trigger circuit 2, the present disclosure can reduce the number of times that determination need be made when the combination is triggered by slightly increasing circuit complexity and decreasing the number of impedance devices, thereby decreasing the occurrence of judgment errors due to the trigger threshold intervals being too small. For every impedance device (the (N+1)^{th} impedance device) added, the times that detection need be made increases by powers of two in order to determine the corresponding combination of the triggers.

It should be noted that, in other embodiments of the present disclosure, each combination of the rest of the triggers of the trigger network triggered could be determined via a detected discharging situation of a resistor-capacitor (RC) circuit.

Reference is next made to FIG. 2C, which is a mapping table of a trigger threshold interval-trigger of the embodiment of the pin-shared trigger circuit according to the present disclosure. The mapping table of the trigger threshold interval-trigger is a voltage-type mapping table. The external circuit 203, through the voltage-type mapping table, determines the voltage interval within which the voltage value detected at the pad 205 falls, so as to determine the correspondingly triggered trigger.

As shown in FIG. 2C, the mapping table of the trigger threshold interval-trigger records the information of each trigger (e.g., trigger name) and its corresponding trigger threshold interval (e.g., a voltage interval within which the trigger is determined triggered). However, the trigger threshold interval of the present disclosure is not limited to only voltage interval.

Further, as shown in FIG. 2C, [0, V(Z1//Z2)) represents that “the interval includes the value of zero but does not include the value of V(Z1//Z2).” Z1//Z2 stands for the impedance devices being in parallel, which further means that if the voltage value detected at the pad falls within this trigger threshold interval, it would correspond to “no triggers triggered,” which is a triggering combination without there being a triggered trigger (i.e., no Click).

[V(Z1//Z2), V(Z1)) represents that “the interval includes the value of V(Z1//Z2) but does not include the value of V(Z1).” That is to say, if the voltage value detected at the pad falls within this trigger threshold interval, it would correspond to “triggering trigger A′+triggering trigger B′,” which is a triggering combination with trigger A′ and trigger B′ being triggered synchronously.

The combinations of “triggering trigger A′” and “triggering trigger B′” can be derived according to the previous description.

Further as shown in FIG. 2C, it should be noted that in the trigger threshold interval-trigger mapping table, the voltage value corresponding to the aforementioned trigger C′ is a constant voltage value, ‘V’. That is to say, if the voltage value detected at the pad is equal to V, then the triggering combination with trigger C′ being triggered is correspondingly obtained.

The design of the trigger threshold interval-trigger mapping table can be self-defined according to practical requirements. The present disclose proposes only a possible implementation of the table, and thus should not be limited thereto.

[Trigger Switch Connected with a Ground Wire]

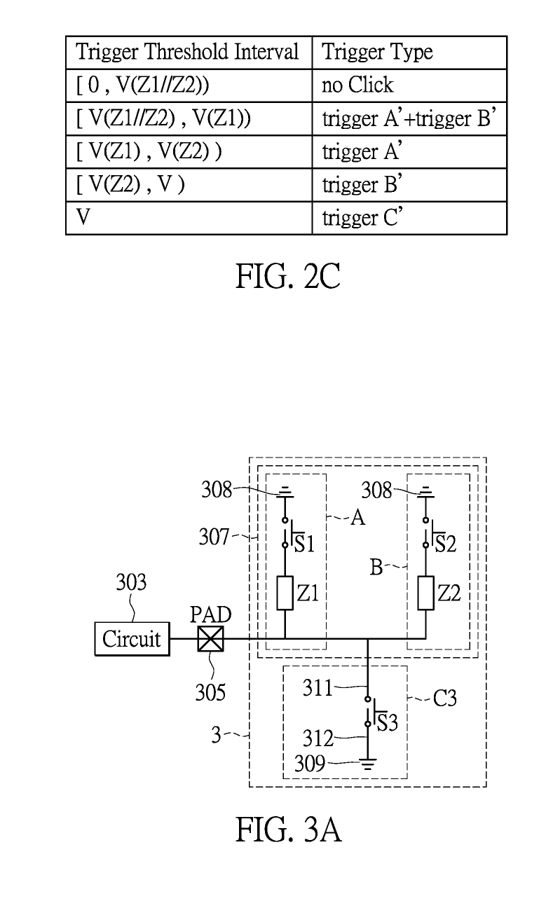

Reference is next made to FIG. 3A, which is another embodiment of a pin-shared trigger circuit of the present disclosure.

As shown in FIG. 3A, the trigger circuit 3 connects with an external circuit 303 through a pad 305. The external circuit 303 can be a determining circuit or other types of circuits.

The trigger circuit 3 includes a trigger switch C3 and a trigger network 307. In the present embodiment, the trigger switch C3 and the trigger network 307 are all circuits. The trigger switch C3 corresponds to one of a plurality of triggers controlling the above-mentioned electronic device, and the trigger network 307 corresponds to a rest of the plurality of triggers controlling the above-mentioned electronic device (i.e., the plurality of triggers with the one corresponding to the trigger switch C3 being excluded).

In the trigger switch C3 of FIG. 3A, the switch S3 electrically connects with the ground wire 309. The trigger switch C3 has a first end 311 and a second 312 respectively connected with the two ends of the switch S3. The first end 311 of the trigger switch C3 electrically connects with the pad 305, and the second end 312 of the trigger switch C3 electrically connects with the ground wire 309. The trigger switch C3 is an electronic loop of the trigger C′. That is to say, when the switch S3 is turned on, the trigger switch C3 is triggered (i.e., trigger C′ is triggered).

In the present embodiment, the second end 312 of the trigger switch C3 electrically connects with the ground wire 309, and the ground wire 309 provides a second voltage value. In the embodiment where the trigger switch C3 is connected with the ground wire 309, the second voltage value detected by the pad 305 is zero.

In FIG. 3A, the trigger network 307 has trigger sub-circuits A and B, and electrically connects with the pad 305. The trigger sub-circuit A is the electronic loop of the trigger A′, and the trigger sub-circuit B is the electronic loop of the trigger B′. That is to say, when switches S1 and S2 are turned on, the trigger sub-circuit A and the trigger sub-circuit B are triggered (i.e., the trigger A′ and the trigger B′ are triggered).

In the trigger sub-circuit A as shown in FIG. 3A, the trigger sub-circuit A has an impedance device Z1, a switch S1 and a ground wire 308. The impedance device Z1 electrically connects with the switch S1 and the ground wire 308. Likewise, a trigger sub-circuit B, has an impedance device Z2, a switch S2 and a ground wire 308. The impedance device Z2 electrically connects with the switch S2 and the ground wire 308. It should be noted that the number of trigger sub-circuits and elements of the trigger network 307 and the ways of connection of the trigger network 307 are not limited in the present disclosure.

Moreover, according to the natural law, the trigger network 307, such an electronic loop, naturally has an impedance value. Further, when the trigger switch C3 is triggered, the current would not flow towards the trigger network 307 due to its impedance value, the current would, however, flow towards the ground wire 309 with relatively smaller impedance (or zero impedance) through the switch S3. Therefore, when a combination of the rest of the triggers corresponding to the trigger switch C3 and the trigger network 307 are simultaneously triggered, the external circuit 303 can detect the second voltage value provided by the ground wire 309 at the pad 305. Furthermore, since the trigger switch C3 would not act simultaneously with other triggers, only a single value determination need be carried out when determining trigger threshold interval.

Reference is next made to FIG. 3B, where FIG. 3B illustrates a trigger threshold interval of another embodiment of the pin-shared trigger circuit of the present disclosure.

Referring to FIGS. 3A and 3B, in the trigger threshold interval of FIG. 3B, the triggering combination (e.g., no triggers triggered, triggering trigger A′, triggering trigger B′, triggering trigger C′) of the plurality of triggers further discerns that the trigger threshold interval-trigger mapping table of the corresponding trigger is a voltage-type mapping table by identifying which trigger threshold interval the voltage value detected when the triggering combination is triggered belongs to. The external circuit 303 determines that the voltage value detected at the pad 305 falls within the voltage interval according to the voltage-type mapping table, and further determines the correspondingly triggered trigger.

In the present embodiment, when the voltage value detected at the pad 305 falls within the interval of V(Z1) and V(Z2), trigger A′ is considered as being triggered; when the voltage value detected at the pad 305 is above V(Z2), trigger B′ is considered as being triggered; when the voltage value detected at the pad 305 falls within the interval of V(Z1//Z2) and V(Z1), trigger A′ and trigger B′ are considered as being triggered simultaneously; and when the voltage value detected at the pad 305 is greater than 0 and under V(Z1//Z2), no trigger is considered as being triggered. Moreover, when the detected voltage value is 0, trigger C′ is considered as being triggered.

To be more specific, in FIG. 3B, an extra determination value (e.g., voltage value 0) of the trigger C′ is shown at the bottom as compared to FIG. 1B. In the trigger circuit 3 proposed by the present disclosure, and with the principle as addressed in FIG. 3A, in addition to relying on the voltage values generated by different combinations of the impedance devices Z1, Z2, another way of determining the triggered trigger is by cooperatively applying the trigger switch C2 connected with the ground wire 309, thereby serving to increase the number of the triggers.

Therefore, via the foregoing trigger circuit 3, the present disclosure can reduce the number of times that determination need be made (e.g. increased by powers of 2) when the combination is triggered by slightly increasing circuit complexity and decreasing the number of impedance devices, thereby decreasing the occurrence of judgment errors due to the trigger threshold intervals being too small.

Reference is next made to FIG. 3C, which is a mapping table of a trigger threshold interval-trigger of another embodiment of the pin-shared trigger circuit according to the present disclosure.

In FIG. 3C, the information of each trigger (e.g., the name of trigger) and the trigger threshold interval each trigger corresponds to (a voltage interval where a trigger is determined to be triggered) are recorded in the table. However, the trigger threshold interval of the present disclosure is not limited to voltage interval only.

In FIG. 3C, [0, V(Z1//Z2)) represents that “the interval includes the value of zero but does not include the value of V(Z1//Z2).” Z1//Z2 stands for the impedance devices being in parallel, which further means that if the voltage value detected at the pad falls within this trigger threshold interval, it would correspond to “no triggers triggered,” which is a triggering combination with no triggers being triggered (i.e., no Click).

[V(Z1//Z2), V(Z1)) represents that “the interval includes the value of the value of V(Z1//Z2) but does not include the value of V(Z1).” That is to say, if the voltage value detected at the pad falls within this trigger threshold interval, it would correspond to “triggering trigger A′+triggering trigger B′,” which is a triggering combination with trigger A′ and trigger B′ being triggered synchronously.

“Triggering trigger A′” and “triggering trigger B′” can be derived according to the previous description.

Further as shown in FIG. 3C, it should be noted that in the trigger threshold interval-trigger mapping table, the voltage value corresponding to the aforementioned trigger C′ is a constant voltage value, ‘V’. That is to say, if the voltage value detected at the pad is equal to the trigger threshold interval, then the triggering combination with trigger C′ being triggered is correspondingly obtained.

The design of the trigger threshold interval-trigger mapping table can be self-defined according to practical requirements. The present disclose proposes only a possible implementation of the table, and thus should not be limited thereto.

### [A Exemplary Embodiment: a Mouse]

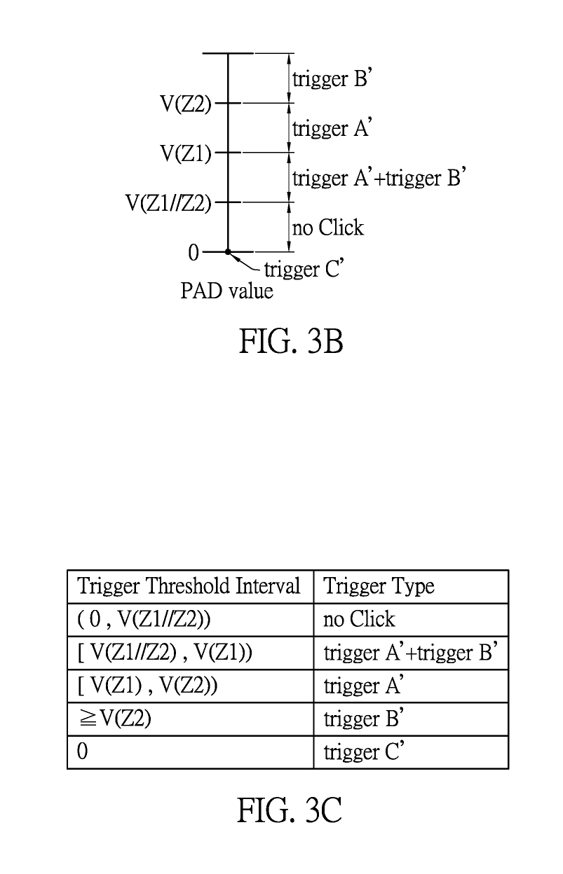

Reference is made to FIG. 4. FIG. 4 is a schematic perspective view illustrating an embodiment of the pin-shared trigger circuit of the present disclosure in application with a mouse.

In the present embodiment, the mouse 4 in FIG. 4 has a left key 405, a right 401 and a middle key 403.

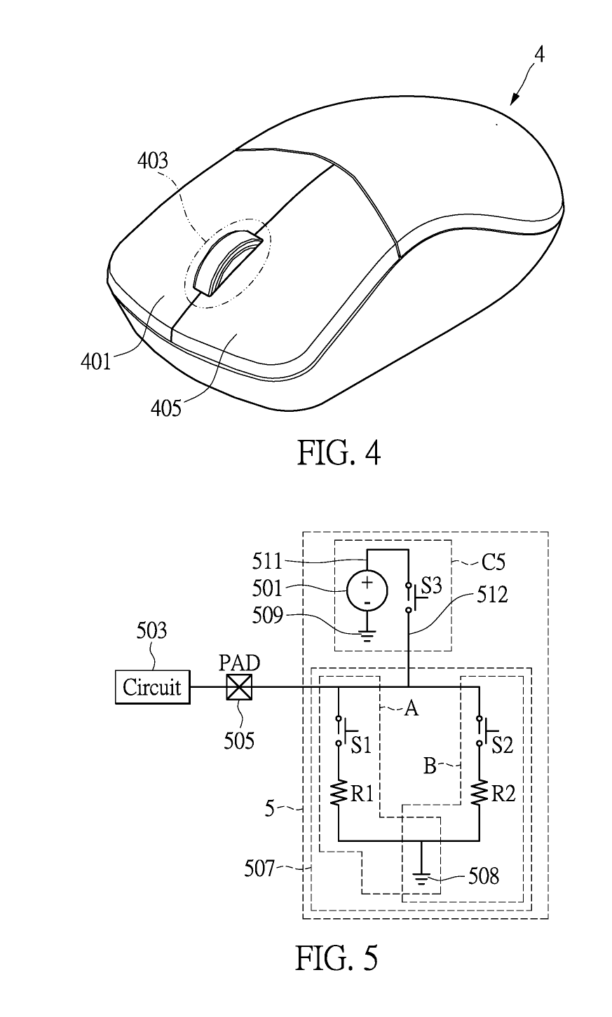

Reference is next made to FIG. 5, which is a diagram of an embodiment of the pin-shared trigger circuit of the present disclosure in application.

In FIG. 5, a trigger circuit 5 of the present embodiment connects with an external circuit 503 through a pad 505. The external circuit 503 could be a determining circuit or other types of circuit.

The trigger circuit 5 includes a trigger switch C5 and a trigger network 507. In the present embodiment, the trigger switch C5 and the trigger network 507 are all circuits. The trigger switch C5 corresponds to one of the plurality of triggers controlling the above-mentioned electronic device, and the trigger network 507 corresponds to the rest of the plurality of triggers controlling the above-mentioned electronic device (i.e., the plurality of triggers with the one corresponding to the trigger switch C5 being excluded).

In the trigger switch C5 of FIG. 5, the trigger switch C5 has a switch S3, a voltage source 501 and a ground wire 509. The switch S3 and the voltage source 501 electrically connect with the ground wire 509. The trigger switch C5 has a first end 511 and a second end 512 respectively connected with the two ends of the switch S3. The first end 511 of the trigger switch C5 electrically connects with the pad 505, and the second end 512 of the trigger switch C5 electrically connects with the voltage source 501. The voltage source 505 provides a first voltage value. The trigger switch C5 is the electronic loop of the trigger C′. That is to say, when the switch S3 is turned on, the trigger switch C2 is triggered (i.e., the trigger C′ is triggered).

In FIG. 5, the trigger network 507 has trigger sub-circuits A and B, and electrically connects with the pad 505. The trigger sub-circuit A is the electronic loop of the trigger A′, and the trigger sub-circuit B is the electronic loop of the trigger B′. That is to say, when switches S1 and S2 are turned on, the trigger sub-circuit A and the trigger sub-circuit B are triggered (i.e., the trigger A′ and the trigger B′ are triggered).

In the trigger sub-circuit A as shown in FIG. 5, the resistor R1 and the switch S1 electrically connect with the ground wire 508. Likewise, in the trigger sub-circuit B, the resistor R2 and the switch S2 electrically connect with the ground wire 508. It should be noted that the number of trigger sub-circuits and elements of the trigger network 507 and the ways of connection of the trigger network 507 are not limited in the present disclosure.

Referring to FIGS. 4 and 5, the applied embodiment in FIG. 4 utilizes the trigger circuit 5 shown in FIG. 5. Under a pin-shared state, the middle key 403 of the mouse 4 is constructed by a constant voltage value generated by the trigger circuit 5.

To be more specific, when clicking the left key 405 of the mouse 4, the switch S1 can be seen as being turned on. At this moment, the external circuit 503 can detect the voltage change caused by the resistor R1 when the trigger sub-circuit A is turned on.

Likewise, when clicking the right key 401 of the mouse 4, the switch S2 can be seen as being turned on. At this moment, the external circuit 503 can detect the voltage change caused by the resistor R2 when the trigger sub-circuit B is turned on.

Furthermore, when clicking the middle key 403 of the mouse 4, the switch S3 can be seen as being turned on. At this moment, the external circuit 503 can detect the voltage change caused by the constant voltage source 509 when the trigger switch C5 is turned on.

The above-mentioned descriptions represent only the exemplary embodiment of the present disclosure, without any intention to limit the scope of the present disclosure thereto. Various equivalent changes, alterations or modifications based on the claims of present disclosure are all consequently viewed as being embraced by the scope of the present disclosure.

What is claimed is:

1. A trigger circuit, which is coupled with a pad, applicable to an electronic apparatus having a plurality of triggers, comprising:
a trigger switch, corresponding to one of the triggers, having a first end and a second end, in which the first end of the trigger switch electrically connects to the pad, and the second end of the trigger switch electrically connects to a voltage source, wherein the voltage source is configured to provide a first voltage value; and
a trigger network, corresponding to a rest of the triggers, in which the trigger network has an impedance value, and has at least one trigger sub-circuit coupled with the pad;
wherein, when the trigger switch is triggered, due to the impedance value of the trigger network, only the first voltage value can be detected at the pad.

2. The trigger circuit as recited in claim 1, wherein, when the trigger switch and at least one of the rest of the triggers are triggered at the same time, only the first voltage value can be detected at the pad.

3. The trigger circuit as recited in claim 1, wherein each combination of the rest of the triggers of the trigger network triggered is determined via a detected voltage value.

4. The trigger circuit as recited in claim 1, wherein each combination of the rest of the triggers of the trigger network triggered is determined via a detected discharging situation of a resistor-capacitor (RC) circuit.

5. The trigger circuit as recited in claim 1, wherein the first voltage value is a positive voltage which is more than zero.

6. The trigger circuit as recited in claim 1, wherein the first voltage value is zero.

7. The trigger circuit as recited in claim 1, wherein the voltage source is a voltage source having a constant voltage output.

8. The trigger circuit as recited in claim 7, wherein the voltage source is a band-gap reference.

9. The trigger circuit as recited in claim 1, wherein the voltage source is a ground wire.

10. The trigger circuit as recited in claim 1, wherein the pad is connected with a determining circuit.

11. The trigger circuit as recited in claim 10, wherein the determining circuit determinates a corresponding combination of the triggers triggered via determining which intervals a voltage value detected at the pad belongs to.

12. The trigger circuit as recited in claim 11, wherein the determining circuit determinates which intervals the voltage value detected at the pad belongs to via a voltage-type mapping table.

13. The trigger circuit as recited in claim 1, wherein the electronic apparatus is a keyboard having an at least two keys.

14. The trigger circuit as recited in claim 1, wherein the electronic apparatus is a touch panel apparatus having an at least two virtual triggers.

15. An apparatus, having a plurality of triggers, comprising:
a trigger circuit including:
a trigger switch, corresponding to one of the triggers, having a first end and a second end, in which the first end of the trigger switch electrically connects to the pad, and the second end of the trigger switch electrically connects to a voltage source, wherein the voltage source has a first voltage value; and
a trigger network, corresponding to a rest of the triggers, in which the trigger network has an impedance value, and has at least one trigger sub-circuit coupled with the pad;
wherein, when the trigger switch is triggered, due to the impedance value of the trigger network, only the first voltage value can be detected at the pad.

16. A computer mouse, having at least a left key, a right key and a central key, comprising:
a trigger circuit including:
a trigger switch, corresponding to one selected from the left key, the right key and the central key, having a first end and a second end, in which the first end of the trigger switch electrically connects to the pad, and the second end of the trigger switch electrically connects to a voltage source, wherein the voltage source has a first voltage value; and
a trigger network, corresponding to a rest of the left key, the right key and the central key, in which the trigger network has an impedance value, and has at least one trigger sub-circuit coupled with the pad;
wherein, when the trigger switches are triggered, due to the impedance value of the trigger network, only the first voltage value can be detected at the pad.
